(19) United States
(12) Patent Application Publication
(10) Pub. No.: US 2019/0036004 A1
(43) Pub. Date: Jan. 31, 2019

(54) STRAIN SENSITIVE PIEZOELECTRIC SYSTEM WITH OPTICAL INDICATOR

(71) Applicant: Intel Corporation, Santa Clara, CA (US)

(72) Inventors: Feras EID, Chandler, AZ (US); Sasha N. OSTER, Marion, IA (US); Shawna M. LIFF, Scottsdale, AZ (US); Johanna M. SWAN, Scottsdale, AZ (US); Thomas L. SOUNART, Chandler, AZ (US); Aleksandar ALEKSOV, Chandler, AZ (US); Valluri R. RAO, Saratoga, CA (US); Baris BICEN, Chandler, AZ (US)

(21) Appl. No.: 16/071,992

(22) PCT Filed: Apr. 1, 2016
(86) PCT No.: PCT/US2016/025654

§ 371 Date: Jul. 23, 2018

(51) Int. Cl. H01L 41/113; H01L 41/047; H01L 41/253; H01L 41/29; H01L 41/316; H01L 41/332; H01L 41/317; H01L 27/20; G01L 1/16

(52) U.S. Cl. CPC H01L 41/1132; H01L 41/1134; H01L 41/047; H01L 41/0475; H01L 41/253; G01L 1/16; H01L 41/316; H01L 41/332; H01L 41/317; H01L 27/20; H01L 41/29

(57) ABSTRACT

Embodiments of the invention include a piezoelectric sensor system. According to an embodiment of the invention, the piezoelectric sensor system may include a piezoelectric sensor, a signal conditioning circuit, and a light source each formed on an organic or flexible substrate. In embodiments of the invention, the piezoelectric sensor may be a discrete component or the piezo electric sensor may be integrated into the substrate. According to an embodiment, a piezoelectric sensor that is integrated into the substrate may comprise, a cavity formed into the organic substrate and a moveable beam formed over the cavity and anchored to the organic substrate. Additionally, the piezoelectric sensor may include a piezoelectric region formed over an end portion of the moveable beam and extending at least partially over the cavity. The piezoelectric sensor may also include a top electrode formed over a top surface of the piezoelectric region.

### FIELD OF THE INVENTION

Embodiments of the present invention relate generally to the manufacture of a strain and/or sensor system suitable for remote sensing. In particular, embodiments of the present invention relate to piezoelectric structures that convert strain or pressure into an electrical output to drive a light source.

### BACKGROUND OF THE INVENTION

Strain gauges have been used to provide outputs that can be correlated to strain or pressure in a system. The use of such sensors is becoming increasingly important with the advancement of machine learning and flexible devices (e.g., wearables, flexible displays, etc.). In machine learning applications a pressure sensor may be used to monitor and adjust the amount of pressure applied by a robotic arm during handling or moving fragile components. With respect to flexible devices, when excessive strain is applied to a flexible device, mechanical or electrical failure of certain components may occur. As such, a pressure sensor may be used to provide an indication to the user that a certain pressure or strain threshold has been reached.

However, current strain gauges have significant limitations that prevent them from being integrated successfully in flexible devices and in certain machine learning applications. One drawback of existing strain gages is that they require an active circuit (e.g., Wheatstone bridge) for measuring the resistance change and then correlating the change in resistance to the amount of pressure applied. Accordingly, an external power source is needed for operation of the strain gage and battery life is reduced. Additionally, strain gages that are currently available produce an electrical signal that needs to be picked up by a circuit that is electrically coupled to the strain gage. As such, remote sensing is not currently possible. Accordingly, if a robotic arm is manipulating a component that is pressure sensitive, the robotic arm needs to be electrically coupled with the component in order to determine the pressure that is being applied to the component.

### BRIEF DESCRIPTION OF THE DRAWINGS

FIG. 1 is a schematic of a sensor system that provides a visual signal when a strain is applied to a piezoelectric sensor, according to an embodiment of the invention.

FIG. 2 is a perspective view illustration of a sensor system on a substrate that can provide a visual signal when a strain is applied to the piezoelectric sensor, according to an embodiment of the invention.

FIG. 3A is a cross-sectional illustration of a piezoelectric sensor with one electrode being a moveable beam that flexes when pressure or strain is applied to the substrate on which the sensor is integrated, according to an embodiment of the invention.

FIG. 3B is cross-sectional illustration of the moveable beam in FIG. 3A, according to an embodiment of the invention.

FIG. 3C is a cross-sectional illustration of the moveable beam in FIG. 3A, according to an additional embodiment of the invention.

FIG. 3D is a plan view illustration of the piezoelectric sensor with a moveable beam that is membrane shaped, according to an embodiment of the invention.

FIG. 3E is a plan view illustration of the piezoelectric sensor with a plurality of moveable beams extending across the cavity, according to an embodiment of the invention.

FIG. 4 is a cross-sectional illustration of a piezoelectric sensor with first and second electrodes formed over a moveable beam that flexes when pressure or strain is applied to the substrate on which the sensor is integrated, according to an embodiment of the invention.

FIG. 5 is a cross-sectional illustration of a piezoelectric sensor that is a discrete component that is mounted on a substrate, according to an embodiment of the invention.

FIG. 6A is a cross-sectional illustration of a substrate after a beam is formed over the top surface of the substrate, according to an embodiment of the invention.

FIG. 6B is a cross-sectional illustration of the substrate after piezoelectric regions are formed over end portions of the moveable beam, according to an embodiment of the invention.

FIG. 6C is a cross-sectional illustration of the substrate after a second electrode is formed over a top surface of the piezoelectric regions, according to an embodiment of the invention.

FIG. 6D is a cross-sectional illustration of the substrate after a cavity is formed below the moveable beam in order to allow for the moveable beam to deflect towards or away from the substrate when pressure or stain is applied, according to an embodiment of the invention.

FIG. 7 is a cross-sectional illustration of a piezoelectric sensor being formed with an insulating layer formed over the beam and an electrode formed over a top surface of the insulating layer, according to an embodiment of the invention.

FIG. 8 is a schematic of a computing device built in accordance with an embodiment of the invention.

### DETAILED DESCRIPTION OF THE INVENTION

Described herein are systems that include a piezoelectric strain and/or pressure sensor formed on a substrate and coupled to a visual indicator and methods of forming such piezoelectric sensors. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Embodiments of the invention include a sensor system that converts a mechanical input (e.g., applied strain or pressure) into an optical output as an indicator of the strain. According to an embodiment, the sensor system relies on a piezoelectric sensor. When strain or pressure is applied to the piezoelectric material, an electrical output (e.g., a voltage) is produced. As such, the sensor systems described in accordance with embodiments of the invention allow for a sensor that may not require an external power source. Since the driving signal to create the optical output is the mechanical strain applied by the user, the amount of power that needs to be provided by a separate power source, such as a battery, is reduced. This is advantageous in cases where long battery life is desired or when it is not practical to frequently remove and change batteries (e.g., in some Internet of Things (IoT)) applications where the sensor or battery are not easily accessible.

According to an embodiment, the electrical output may be used to activate a light source. For example, the light source may be a light emitting diode (LED). Since an optical light source is used to measure the strain, monitoring the strain does not require a wired connection to the device, thereby enabling remote sensing. This is particularly advantageous in machine learning applications. As an example, if a robotic arm is handling a pressure sensitive object, a detector on the robotic arm that is sensitive to the light (e.g., a photodetector) may be used to detect the intensity of the light emitted by the light source.

In some embodiments of the invention, the piezoelectric sensor may be fabricated into the substrate itself. The removal of an additional package to house the piezoelectric sensor reduces the thickness of the device. Additionally, manufacturing piezoelectric sensors into organic substrates allows for a decrease in the manufacturing cost. Previously, piezoelectric components needed to be manufactured on substrates that can withstand high temperatures, such as silicon substrates. High temperature compatible substrates such as these were used because the piezoelectric material needed to be annealed at temperatures greater than approximately 500° C. in order to crystallize the piezoelectric material. However, embodiments of the present invention allow for piezoelectric material to be deposited and crystalized at much lower temperatures by using a pulsed laser annealing process, described in greater detail below. Therefore, piezoelectric sensors are able to be fabricated on low temperature organic substrates that are typically used in package and board manufacturing. Furthermore, flexible substrates are also commonly low temperature organic materials. As such, embodiments of the invention allow for the integration of piezoelectric sensors into flexible devices, thereby enabling the use in wearables and flexible displays.

Technologies and materials developed for package/board processing are significantly less expensive than technologies and materials used for semiconductor processing. Fabricating piezoelectric sensors directly in the substrate or board reduces the cost over piezoelectric components formed on silicon because of the large panels (e.g., 510 mm×515 mm) used for organic substrate and board fabrication. Since organic substrates are usually batch manufactured in large panels, large area integration of piezoelectric sensors is also facilitated by embodiments of the invention. This enables the parallel manufacturing of large numbers of piezoelectric sensors cost-effectively. Additionally, the materials used in package and board systems are less expensive than silicon-based devices. Furthermore, since the piezoelectric sensors may be directly manufactured as part of the package substrate or board, they do not require an additional assembly operation.

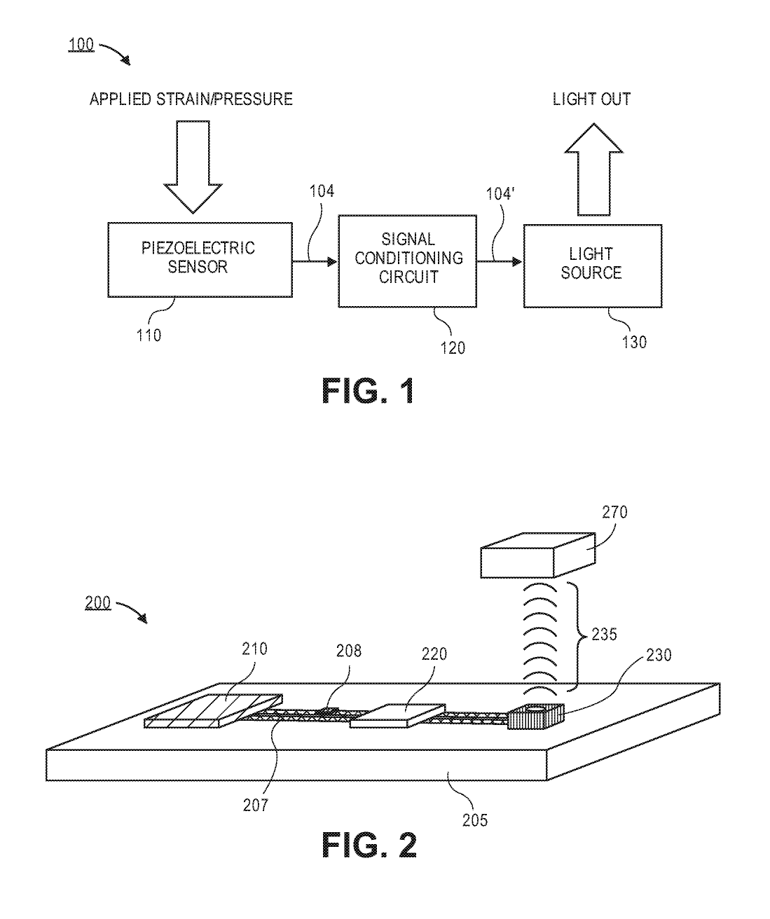

Referring now to FIG. 1 a schematic of a sensor system 100 is illustrated, according to an embodiment of the invention. As illustrated, the sensor system 100 may include a piezoelectric sensor 110 and a light source 130. The piezoelectric sensor 110 receives an applied strain or pressure (as indicated by the arrow pointing towards the piezoelectric sensor 110) and generates an electrical output 104. The electrical output 104 activates the light source 130 and results in an optical output (as indicated by the arrow pointing away from the light source 130). In some embodiments, the optical output may be proportional to the stain or pressure applied to the system. This optical output can then be used as an indicator for quantifying and/or adjusting the amount of strain or pressure applied to the device. In other embodiments, the optical output may be digital and indicate when a predetermined strain or pressure threshold has been met.

According to an embodiment, the sensor system 100 may optionally include a signal conditioning circuit 120. The signal conditioning circuit 120 may include circuitry that converts the electrical output 104 generated by the piezoelectric sensor 110 into an appropriate input 104′ for driving the light source 130. For example, the conditioning circuit may include an amplifier, a comparator, or any other circuitry needed to modify the electrical output 104.

In one embodiment, the sensor system 100 may be operated in a digital (i.e., on/off) mode. In such embodiments, a predetermined strain or pressure threshold may be set so that the light source 130 is activated before mechanical or electrical damage occurs to the system being monitored. For example, the light source 130 may remain off as long as the strain or pressure applied to the sensor is below the predetermined threshold, and the light source 130 may be activated when the strain or pressure exceeds the threshold value. Accordingly, when the light source 130 is activated, the user of the system is provided with an optical indication that no additional stress or pressure should be applied to the device. In an embodiment where a digital mode of operation is used, the signal conditioning circuit 120 may include a comparator. The comparator may be used to compare a voltage obtained from the piezoelectric sensor 110 to a voltage associated with the predetermined threshold value. When the electrical output 104 from the piezoelectric sensor 110 exceeds the predetermined threshold value, the signal conditioning circuit may then deliver an input 104′ to the light source 130 to cause the light source to turn on.

An additional embodiment of the invention may omit the signal conditioning circuit 120 when a digital mode of operation is desired. In such an embodiment, the light source 130 may be chosen so that the forward voltage required to turn on the light source 130 is equal to the predetermined threshold value. Accordingly, the electrical output 104 from the piezoelectric sensor will only activate the light source 130 when the strain or pressure exceeds a predetermined value. In one example, a light emitting diode (LED) may be used as the light source 130.

In another embodiment, the sensor system 100 may be operated in an analog mode. Such an embodiment may be particularly useful to determine the actual strain or pressure that is being applied to the piezoelectric sensor. The intensity of the light emitted by the light source 130 may be proportional to the voltage produced by the piezoelectric sensor 110. Accordingly, when the sensor system 100 has been calibrated, a strain or pressure value may be correlated with the intensity of the light emitted from the light source. For example, the intensity of the light may be determined by an optical sensor (not shown in FIG. 1), such as a photodetector. According to an embodiment, the optical sensor may be mounted on a device other than the device the sensor system 100 is formed on, and may be used to control the pressure applied by a machine or robot to the device on which sensor system 100 is formed. As such, remote sensing of the strain or pressure may be possible since no electrical trace is needed to carry the signal to the remote sensing device. Such embodiments may be particularly useful in machine learning applications. For example, a robotic arm may adjust the pressure it applies to a device depending on the intensity of light emitted by the sensor system 100, thereby allowing for handling or transferring fragile components.

Referring now to FIG. 2, a perspective view illustration of a sensor system 200 is shown, according to an embodiment of the invention. In an embodiment, the sensor system 200 may be formed on a substrate 205. For example, the substrate 205 may be a bendable or otherwise flexible substrate. In one embodiment, the substrate 205 is an organic substrate. By way of example, the substrate 205 may be a polymer material, such as, for example, polyimide, epoxy, or build-up film. The substrate 205 may include one or more layers (i.e., build-up layers). As illustrated, the piezoelectric sensor 210 may be formed on a surface of the substrate 205. For example, the piezoelectric sensor 210 may be a discrete component (as is illustrated in FIG. 2), or the piezoelectric sensor 210 may be integrated directly into the substrate 205, as will be described in greater detail below. Additionally, while the piezoelectric sensor 210 is illustrated as being on the top surface of the substrate 205, it is to be appreciated that the piezoelectric sensor 210 may be formed within the substrate 205. As such, stresses or pressures within a packaged device may be measured as well.

In an embodiment, the electrical output from the piezoelectric sensor 210 may be sent to the signal conditioning circuit 220 and/or the light source 230 by conductive traces 207 formed on or in the substrate. The conductive traces may be any suitable conductive material, such as copper, tin, aluminum, alloys of conductive materials, and may also include multiple layers, such as seed layers, barrier layers, or the like. Furthermore, while the conductive traces 207 are illustrated as being substantially straight line connections between components, embodiments of the invention are not limited to such configurations. For example, the conductive traces 207 may be formed in a meandering pattern that allows for greater flexing, stretching, bending, or the like, before being damaged.

According to an embodiment, the sensor system 200 may also include one or more strain recording components 208. A strain recording component 208 may be a device that indicates that a certain level of strain has been applied to the device. A strain recording component 208 may allow for easy inspection (e.g., for warranty protection). For example, a warranty may be voided by extreme use of the device (e.g., a user may negligently apply strain or pressure far beyond normal usage). As such, a manufacture who needs to determine whether the warranty was voided or not may inspect the strain recording component 208 to see if damage will be covered by the warranty. In an embodiment, the strain recording component 208 may be a fuse. The fuse may be chosen so that any strain or pressure beyond normal usage will generate an electrical output signal from the piezoelectric sensor 210 that will blow the fuse. As such, when the fuse is blown, the warranty may be voided. Since a fuse 208 requires no additional power or memory to permanently record the excessive strain, power consumption and cost of the device are not significantly increased.

While the strain recording component 208 is shown as being positioned along a conductive trace 207, embodiments are not limited to such configurations. For example, the strain recording component 208 may be formed as part of the sensor 210, the signal conditioning circuit 220, the light source 230, or any other location in the piezoelectric sensor system 200. Furthermore, while a fuse is included as one example of a strain recording device 208, embodiments are not so limited. For example, the strain recording device 208 may be a memory on the signal conditioning circuit 220 that can be recorded on when an excessive strain or pressure is applied to the substrate 205. During inspection, if the memory on the signal conditioning circuit 220 has recorded that excessive strain was applied, then the warranty may be voided.

Embodiments may also include a signal conditioning circuit 220. As illustrated, the signal conditioning circuit 220 may be mounted to the substrate 205. For example, the signal conditioning circuit may be a die that is surface mounted to the substrate. The die may include any suitable circuitry, such as a comparator, an amplifier, etc. For example, the signal conditioning circuit 220 may be an application-specific integrated circuit (ASIC).

According to an embodiment, the light source 230 may also be mounted to the substrate 205. The light source 230 may be any suitable light source. In one embodiment, the light source 230 may include one or more LEDs. As illustrated in FIG. 2, a photodetector 270 may be used to detect light 235 that is emitted from the light source 230. Since the photodetector 270 does not require an electrical signal from the piezoelectric sensor 210, the photodetector 270 can be located remotely from the substrate. While illustrated as being a single component, the photodetector 270 may be integrated into any other device besides the substrate 205. For example, the photodetector 270 may be mounted on a robot that is used to manipulate the substrate 205 (e.g., pick up, adjust, or otherwise move the substrate 205).

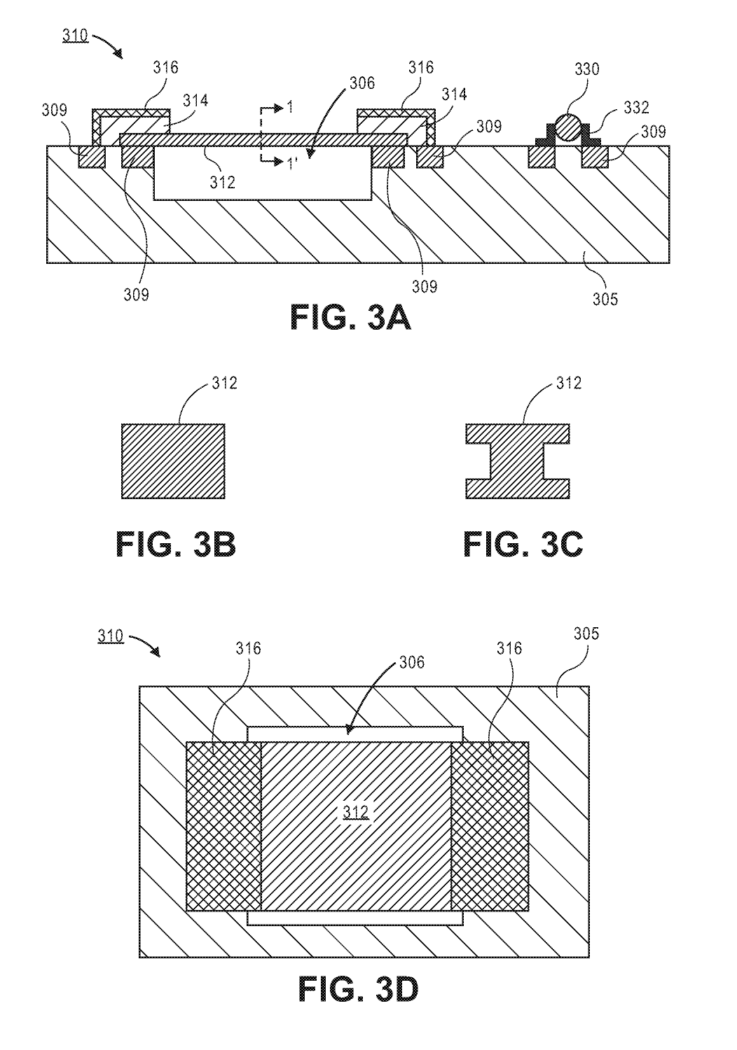

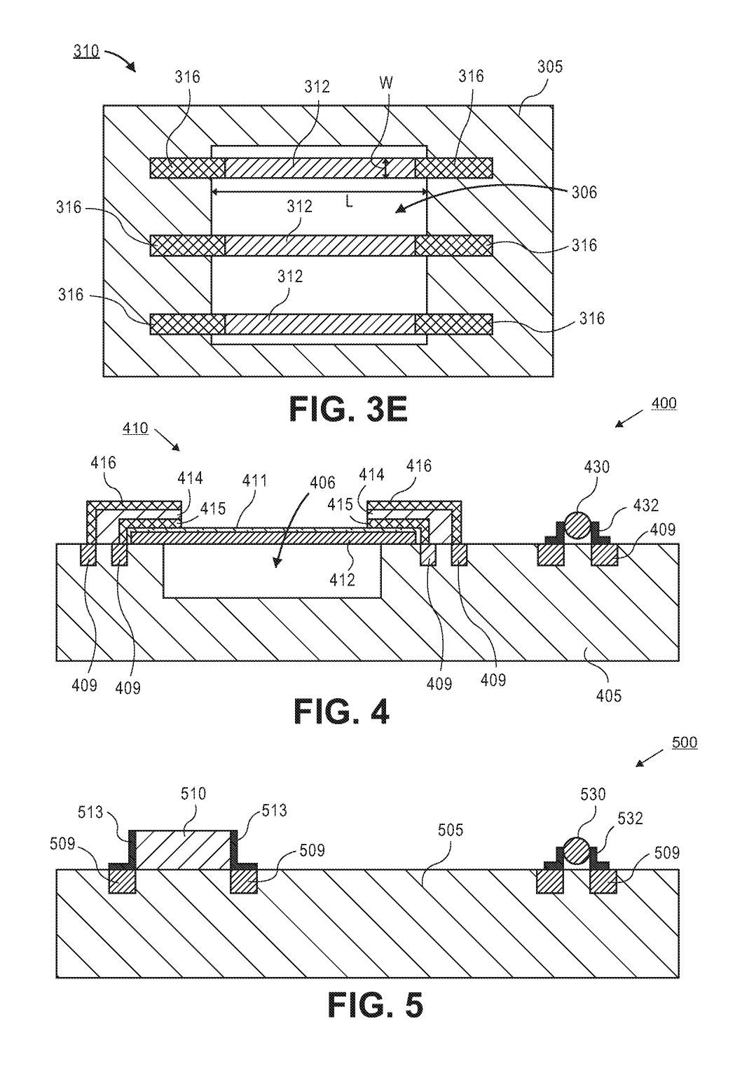

Referring now to FIG. 3A, a cross-sectional illustration of a sensor system 300 is illustrated according to an embodiment of the invention. In the illustrated embodiment, a piezoelectric sensor 310 and a light source 330 are shown, though it is to be appreciated that a conditioning circuit may also be included. According to an embodiment, the piezoelectric sensor 310 may be electrically coupled to the light source 330 by one or more conductive traces (not shown in FIG. 3A) that are formed between conductive pads or vias 309. In an embodiment, the light source 330 may be mounted to the conductive pads 309 by contacts 332. The contacts 332 may be coupled to the pads 309 with any structure typically used in surface mounted components. For example, the light source 330 may be coupled to the pads 309 with solder, conductive epoxy, anisotropic conductive film or paste, or the like.

In the illustrated embodiment, the piezoelectric sensor 310 is integrated into the substrate 305. According to an embodiment, the piezoelectric sensor 310 includes a moveable beam 312 that spans across a cavity 306 formed in the substrate 305. For example, the moveable beam 312 may be anchored at each end to the substrate 305 and/or a conductive pad or via 309. Since a central portion of the moveable beam 312 is not supported from below, the central portion of the moveable beam 312 may be displaced towards or away from the substrate when strain or pressure is applied to the substrate 305. The extent of the displacement of the moveable beam 312 is measured by converting the mechanical deformation into an electrical output with piezoelectric regions 314 formed proximate to the ends of the moveable beam 312. The deflection of the moveable beam 312 induces strain in the piezoelectric regions 314, which generates a voltage across the piezoelectric region 314 that is proportional to the strain or pressure. In order to detect the amount of deflection, the piezoelectric regions 314 may extend out over the cavity 306. Since the piezoelectric regions 314 are mechanically coupled to the central portion of the moveable beam 312 that deflects under pressure or strain, the piezoelectric regions will also be strained, thereby producing an output voltage. While the piezoelectric regions 314 are shown on both ends of the moveable beam 312, embodiments are not limited to such configurations. For example, a piezoelectric region 314 may be formed on only one end of the moveable beam 312. According to an additional embodiment of the invention, the piezoelectric region 314 may extend across the entire moveable beam 312.

In order to transfer the voltage generated by the piezoelectric regions 314 to the light source 330, electrodes are formed above and below the piezoelectric regions 314. In one embodiment, the moveable beam may be used as one of the electrodes, and the piezoelectric region 314 may be formed directly over the moveable beam 312. Additionally, a second electrode 316 may be formed over a top surface of the piezoelectric regions 314. According to an embodiment, the second electrode 316 and the moveable beam 312 may be any suitable conductive material (e.g., copper, aluminum, alloys, etc.). In order to deliver the voltage from the piezoelectric regions 314 to the light source 330, the electrode 316 and the moveable beam 312 may be electrically coupled to the conductive pads or vias 309 on the substrate 305. In an additional embodiment, the electrodes 316 and the moveable beam 312 may be electrically coupled directly to conductive traces (not shown) and the conductive pads 309 may be omitted.

It is to be appreciated that piezoelectric material typically requires a high temperature anneal (e.g., greater than 500° C.) in order to provide the proper crystal structure to produce the piezoelectric effect. As such, depositing piezoelectric material generally requires a substrate that is capable of withstanding high temperatures (e.g., silicon). Flexible substrates, such as organic substrates described herein, typically cannot withstand temperatures above 260° C. However, embodiments of the present invention allow for piezoelectric regions 314 to be formed at much lower temperatures. For example, instead of a high temperature anneal, embodiments include depositing the piezoelectric regions 314 in an amorphous phase and then using a pulsed laser to crystallize the piezoelectric regions 314. According to an embodiment, the laser annealing process may use an excimer laser with an energy density between approximately 10-100 mJ/cm² and pulse width between approximately 10-50 nanoseconds. For example, the piezoelectric regions 314 may be deposited with a sputtering process, an ink jetting process, or the like. According to an embodiment, the piezoelectric layer may be lead zirconate titanate (PZT), potassium sodium niobate (KNN), zinc oxide (ZnO), aluminum nitride (AlN), or combinations thereof.

Referring now to FIGS. 3B and 3C, cross-sectional views of the moveable beam 312 along line 1-1′ in FIG. 3A are shown, according to embodiments of the invention. In FIG. 3B, the cross-sectional view of the beam illustrates a substantially rectangular cross-section. However, additional embodiments of the invention may include any desired cross-sectional shape for the moveable beam 312. For example, in FIG. 3C an I-shaped cross-section is shown. Altering the cross-section of the moveable beam 312 may allow for the stiffness of the beam to be increased or decreased, depending on the needs of the device. Such a structure may be formed with multiple lithography and patterning operations during the fabrication of the moveable beam 312. While an I-shaped cross-section is illustrated in FIG. 3C, it is to be appreciated that the cross-section may be any desired shaped (e.g., T-shaped, square, rectangular, stepped, etc.).

Referring now to FIGS. 3D and 3E, a pair of plan view illustrations of piezoelectric sensors 310 are shown, according to embodiments of the invention. In FIG. 3D, the moveable beam 312 is shown as having a substantially rectangular shape that spreads substantially along the length of the cavity 306. Such a shape may be referred to as a membrane due to the relatively large surface area compared to the thickness of the moveable beam 312. Additionally, embodiments of the invention may include a moveable beam 312 that is significantly more narrow, as is shown in FIG. 3E. In such an embodiment, the length L of the moveable beam 312 may be significantly greater than a width W of the moveable beam 312. Furthermore, embodiments of the invention may include one or more moveable beams 312 spanning across a single cavity 306. The inclusion of more than one moveable beam 312 may provide redundancy to the piezoelectric sensor 310. For example, if one of the moveable beams 312 suffers from mechanical or electrical failure, the additional moveable beams 312 may still allow for the piezoelectric sensor 310 to function properly.

Referring now to FIG. 4, a cross-sectional illustration of a sensor system 400 is shown, according to an additional embodiment of the invention. The sensor system 400 in FIG. 4 is substantially similar to the sensor system 300 illustrated in FIG. 3A, with the exception that the moveable beam 412 is not used as an electrode. According to an embodiment, the moveable beam 412 may be electrically isolated from the piezoelectric regions 414 and the electrodes by an electrically insulating layer 411. The electrically insulating layer 411 may be any suitable non-conductive material. For example, the insulating layer 411 may be an inorganic insulator, such as a nitride or an oxide (e.g., silicon nitride (SiN) or silicon oxide (SiO₂)).

In order to generate an electrical output when the moveable beam 412 is deflected, an additional electrode 415 may be formed in contact with the piezoelectric region 414. The electrode 415 may be formed directly over the insulating layer 411. Additionally, the electrode 415 may be electrically coupled to a conductive pad or via 409 on the substrate 405. As such, the voltage generated across the piezoelectric region 414 may be transmitted to the light source 430, even when the moveable beam 412 is not part of the conductive path between the piezoelectric sensor 410 and the light source 430.

Referring now to FIG. 5, a cross-sectional illustration of a sensor system 500 is shown, according to an additional embodiment of the invention. The sensor system 500 is substantially similar to the sensor systems 300 and 400 described above, with the exception that the piezoelectric sensor 510 is not integrated directly into the substrate 505. Instead, embodiments of the invention may include a discrete piezoelectric sensor 510 that is surface mounted to pads 509 on the substrate 505. According to an embodiment, the discrete piezoelectric sensor 510 may be any type of piezoelectric sensor. For example, the piezoelectric sensor 510 may be formed on an organic substrate with a pulsed laser annealing process similar to the piezoelectric regions described herein, or the discrete piezoelectric sensor 510 may be a piezoelectric sensor that is fabricated on a high temperature substrate, such as a silicon substrate. In an embodiment, the piezoelectric sensor 510 may be mounted to the conductive pads 509 by contacts 513. The contacts 513 may be coupled to the pads 509 with any structure typically used in surface mounted components. For example, the piezoelectric sensor 510 may be coupled to the pads 509 with solder, conductive epoxy, anisotropic conductive film or paste, or the like.

While the piezoelectric sensor 510 is not integrated into the substrate 505, several benefits still remain when the piezoelectric sensor 510 is used in the sensing system 500. For example, the power consumption of the device is still decreased compared to typical strain gauges, such as those described above. Even though it is a discrete component, the piezoelectric sensor 510 is able to generate an output voltage that is proportional to the strain or pressure applied. As such, the light source 530 may be driven without significantly increasing power consumption of the device. Additionally, the combination of the piezoelectric sensor 510 and the light source 530 allows for remote sensing, similar to the sensor systems described above.

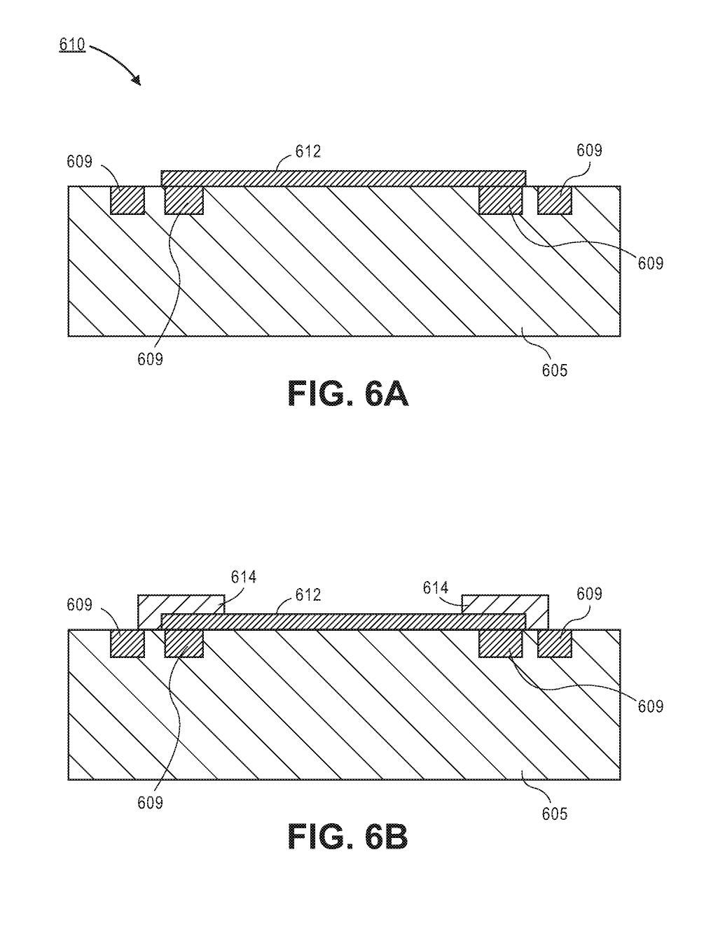

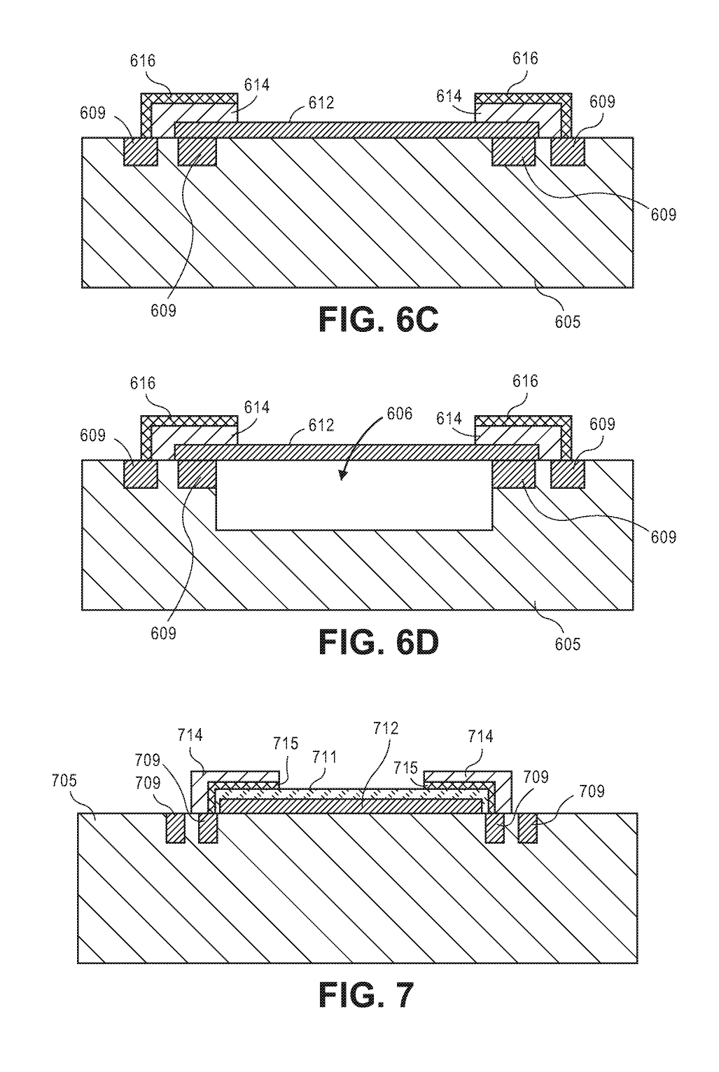

Referring now to FIGS. 6A-6D, a process flow for forming a piezoelectric sensor is shown, according to an embodiment of the invention. Referring now to FIG. 6A, the structure that will form the moveable beam 612 is formed over a top surface of a substrate 605. According to an embodiment, the moveable beam 612 may be formed with manufacturing processes known in the semiconductor and substrate manufacturing industries, such as semi-additive processing, subtractive processing, or the like.

Referring now to FIG. 6B, the piezoelectric regions 614 may be formed over the end regions of moveable beam 612. According to an embodiment, the piezoelectric regions 614 may be deposited in an amorphous phase. In order to improve the piezoelectric properties of the piezoelectric regions 614, the amorphous layer may be crystallized with a laser annealing process. For example, the piezoelectric regions 614 may be deposited with a sputtering process, an ink jetting process, or the like. According to an embodiment, the piezoelectric regions 614 may be PZT, (KNN), ZnO, AN, or combinations thereof. In an embodiment, the laser annealing process may be a pulsed laser anneal and implemented so that the temperature of the substrate 605 does not exceed approximately 260° C. As such, embodiments of the invention allow for piezoelectric regions 614 to be formed on low temperature substrates, such as organic substrates. Accordingly, the piezoelectric sensor may be integrated onto flexible substrates that allow uses such as, wearables, flexible displays, or the like.

While FIG. 6B illustrates that the piezoelectric regions 614 are formed directly on the moveable beam 612, embodiments are not limited to such configurations. Referring briefly ahead to FIG. 7, an additional embodiment of the invention illustrates a processing procedure, where an electrically insulating layer 711 is formed directly over the moveable beam (similar to the piezoelectric sensor illustrated in FIG. 4). In such embodiments, an electrode 715 may be formed over the electrically insulating layer 711. The piezoelectric region 714 may then be formed over the electrode 715 in a manner substantially similar to the process described above with respect to FIG. 6B. After the piezoelectric region 614 is formed, the processing may proceed in substantially the same manner described with respect to FIGS. 6C and 6D, in order to produce a piezoelectric sensor substantially similar to the one illustrated and described with respect to FIG. 4.

Returning back to the process flow in FIGS. 6A-6D, FIG. 6C illustrates electrodes 616 having been formed over the piezoelectric regions 614. According to an embodiment, the electrodes 616 may be formed with damascene processes, electroless or electrolytic plating, sputtering, evaporation, or other processes. As illustrated, the electrodes 616 may be electrically coupled to conductive pads or vias 609 on the substrate 605 that are electrically isolated from the conductive pads or vias 609 that are connected to the moveable beam 612. Accordingly, when a voltage is generated across the piezoelectric regions 614, the voltage may be transmitted to a light source that will be coupled to the conductive pads or vias 609.

Referring now to FIG. 6D, the moveable beam 612 is released from the substrate 605 in order to allow for actuation. The moveable beam 612 may be released by forming a cavity 606 below a portion of the moveable beam 612. For example, the cavity 606 may be formed with a photolithography and etching process that selectively removes the portion of the substrate 605 below the moveable beam 612. For example, the etching process may be a reactive ion etching process, or any other dry or wet etching process. In embodiments where the moveable beam 612 is too large to allow for adequate removal of the substrate 605 below the pad (i.e., the moveable beam functions as an etch mask to the substrate 605 below), one or more holes may be formed through the moveable beam 612 to allow for the chemistry from the etching process to pass through the moveable beam 612 and remove the substrate 605 below. Forming holes through the moveable beam 612 may be particularly beneficial when the moveable beam 612 is membrane shaped, similar to the moveable beam 312 in FIG. 3D, since the relatively large surface area of the moveable beam may prevent removal of portions of the substrate below the membrane.

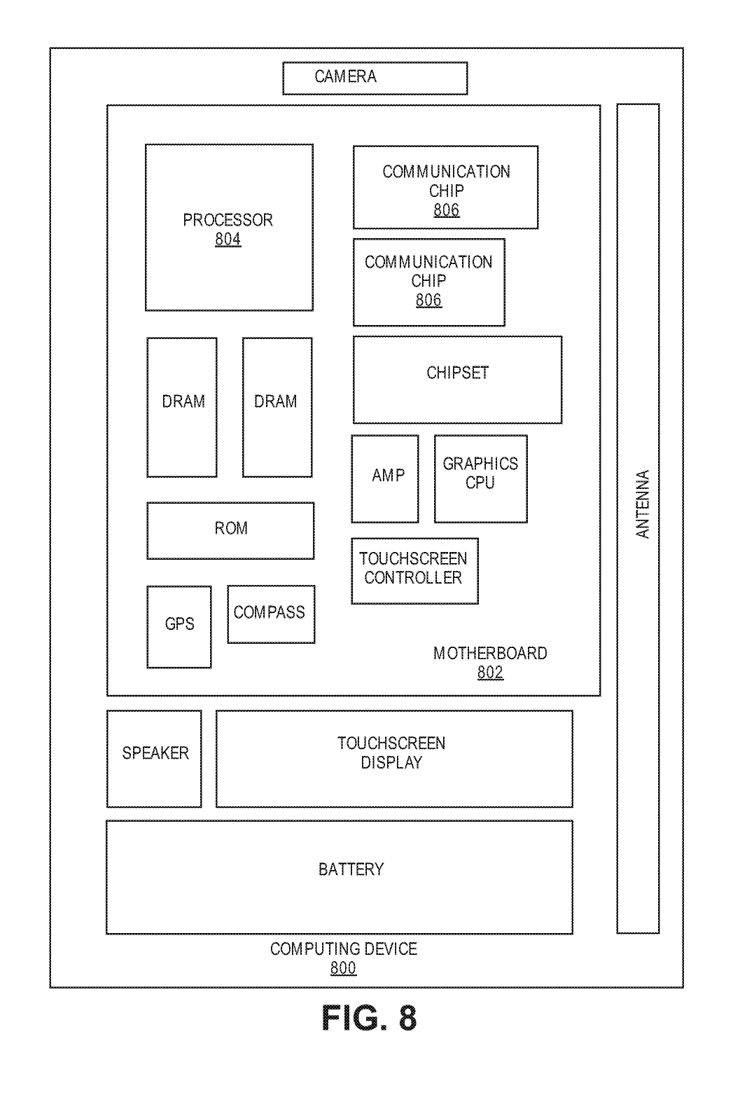

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be packaged on an organic substrate that includes one or more piezoelectric sensors, in accordance with implementations of the invention. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be packaged on an organic substrate that includes one or more piezoelectric sensors, in accordance with implementations of the invention.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Embodiments of the invention include a piezoelectric sensor, comprising: a cavity formed into an organic substrate; a moveable beam formed over the cavity and anchored to the organic substrate; a piezoelectric region formed over an end portion of the moveable beam, wherein the piezoelectric region extends at least partially over the cavity; and a top electrode formed over a top surface of the piezoelectric region.

Additional embodiments of the invention include a piezoelectric sensor, wherein the top electrode is electrically coupled to a first conductive pad or via, and wherein the moveable beam is electrically coupled to a second conductive pad or via.

Additional embodiments of the invention include a piezoelectric sensor, wherein the moveable beam has a uniform cross-section.

Additional embodiments of the invention include a piezoelectric sensor, wherein the moveable beam has an I-shaped cross-section.

Additional embodiments of the invention include a piezoelectric sensor, wherein the moveable beam has a length that is substantially greater than a width of the moveable beam.

Additional embodiments of the invention include a piezoelectric sensor, further comprising: an electrically insulating layer formed on a top surface of the moveable beam; and a bottom electrode formed over the electrically insulating layer, wherein the bottom electrode contacts the piezoelectric region.

Additional embodiments of the invention include a piezoelectric sensor, wherein the bottom electrode and the top electrode are each coupled to a different conductive pad or via on the substrate, and wherein the moveable beam is not electrically coupled to the piezoelectric region.

Embodiments of the invention include a sensor system, comprising: an organic substrate; a piezoelectric sensor coupled to the organic substrate; and a light source electrically coupled to the piezoelectric sensor, wherein an intensity of light emitted by the light source is at least partially controlled by an electrical output signal generated by the piezoelectric sensor.

Additional embodiments of the invention include a sensor system, wherein the piezoelectric sensor is a discrete component mounted to the organic substrate.

Additional embodiments of the invention include a sensor system, wherein the piezoelectric sensor is integrated into the organic substrate.

Additional embodiments of the invention include a sensor system, wherein the piezoelectric sensor comprises: a cavity formed into the organic substrate; a moveable beam formed over the cavity and anchored to the organic substrate; a piezoelectric region formed over an end portion of the moveable beam, wherein the piezoelectric region extends at least partially over the cavity; and a top electrode formed over a top surface of the piezoelectric region.

Additional embodiments of the invention include a sensor system, wherein the top electrode and the moveable beam are electrically coupled to the light source.

Additional embodiments of the invention include a sensor system, wherein the piezoelectric sensor further comprises: an electrically insulating layer formed on a top surface of the moveable beam; and a bottom electrode formed over the electrically insulating layer, wherein the bottom electrode contacts the piezoelectric region.

Additional embodiments of the invention include a sensor system, wherein the bottom electrode and the top electrode are each electrically coupled to the light source, and wherein the moveable beam is not electrically coupled to the piezoelectric region.

Additional embodiments of the invention include a sensor system, wherein the piezoelectric sensor and the light source are electrically coupled by one or more conductive traces.

Additional embodiments of the invention include a sensor system, wherein the conductive traces are meandering traces.

Additional embodiments of the invention include a sensor system, further comprising:

an electrical output conditioning circuit electrically coupled to the piezoelectric sensor, wherein the electrical output conditioning circuit modifies the electrical output signal generated by the piezoelectric sensor before it is delivered to the light source.

Additional embodiments of the invention include a sensor system, wherein the electrical output conditioning circuit includes an amplifier and/or a comparator.

Embodiments of the invention include a method of forming a piezoelectric sensor, comprising: forming a beam over an organic substrate; depositing a piezoelectric material over portions of the beam, wherein the piezoelectric layer has a substantially amorphous crystal structure; crystallizing the piezoelectric material with a pulsed laser anneal, wherein a temperature of the organic substrate does not exceed 260° C.; forming an electrode over a top surface of the piezoelectric material; and forming a cavity below a portion of the beam.

Additional embodiments of the invention include a method of forming a piezoelectric sensor, wherein the piezoelectric layer is deposited with a sputtering or ink-jetting process.

Additional embodiments of the invention include a method of forming a piezoelectric sensor, wherein the cavity is formed with a reactive ion etching process.

Additional embodiments of the invention include a method of forming a piezoelectric sensor, wherein the piezoelectric layer and the second electrode do not completely cover a top surface of the first electrode.

Embodiments of the invention include a sensor system for controlling a machine, comprising: an organic substrate; a piezoelectric sensor coupled to the organic substrate; a light source electrically coupled to the piezoelectric sensor, wherein an intensity of light emitted by the light source is at least partially controlled by an electrical output signal generated by the piezoelectric sensor; an electrical output conditioning circuit electrically coupled to the piezoelectric sensor, wherein the electrical output conditioning circuit modifies the electrical output signal generated by the piezoelectric sensor before it is delivered to the light source; and a photodetector mounted remotely from the organic substrate.

Additional embodiments of the invention include a sensor system for controlling a machine, wherein the piezoelectric sensor comprises: a cavity formed into the organic substrate; a moveable beam formed over the cavity and anchored to the organic substrate; a piezoelectric region formed over an end portion of the moveable beam, wherein the piezoelectric region extends at least partially over the cavity; and a top electrode formed over a top surface of the piezoelectric region.

Additional embodiments of the invention include a sensor system for controlling a machine, wherein the piezoelectric sensor further comprises: an electrically insulating layer formed on a top surface of the moveable beam; and a bottom electrode formed over the electrically insulating layer, wherein the bottom electrode contacts the piezoelectric region.

What is claimed is:

1. A piezoelectric sensor, comprising:
a cavity formed into an organic substrate;
a moveable beam formed over the cavity and anchored to the organic substrate;
a piezoelectric region formed over an end portion of the moveable beam, wherein the piezoelectric region extends at least partially over the cavity; and
a top electrode formed over a top surface of the piezoelectric region.

2. The piezoelectric sensor of claim 1, wherein the top electrode is electrically coupled to a first conductive pad or via, and wherein the moveable beam is electrically coupled to a second conductive pad or via.

3. The piezoelectric sensor of claim 1, wherein the moveable beam has a uniform cross-section.

4. The piezoelectric sensor of claim 1, wherein the moveable beam has an I-shaped cross-section.

5. The piezoelectric sensor of claim 1, wherein the moveable beam has a length that is substantially greater than a width of the moveable beam.

6. The piezoelectric sensor of claim 1, further comprising:
an electrically insulating layer formed on a top surface of the moveable beam; and
a bottom electrode formed over the electrically insulating layer, wherein the bottom electrode contacts the piezoelectric region.

7. The piezoelectric sensor of claim 6, wherein the bottom electrode and the top electrode are each coupled to a different conductive pad or via on the substrate, and wherein the moveable beam is not electrically coupled to the piezoelectric region.

8. A sensor system, comprising:
an organic substrate;
a piezoelectric sensor coupled to the organic substrate; and
a light source electrically coupled to the piezoelectric sensor, wherein an intensity of light emitted by the light source is at least partially controlled by an electrical output signal generated by the piezoelectric sensor.

9. The sensor system of claim 8, wherein the piezoelectric sensor is a discrete component mounted to the organic substrate.

10. The sensor system of claim 8, wherein the piezoelectric sensor is integrated into the organic substrate.

11. The sensor system of claim 10, wherein the piezoelectric sensor comprises:
a cavity formed into the organic substrate;
a moveable beam formed over the cavity and anchored to the organic substrate;
a piezoelectric region formed over an end portion of the moveable beam, wherein the piezoelectric region extends at least partially over the cavity; and
a top electrode formed over a top surface of the piezoelectric region.

12. The sensor system of claim 11, wherein the top electrode and the moveable beam are electrically coupled to the light source.

13. The sensor system of claim 11, wherein the piezoelectric sensor further comprises:
an electrically insulating layer formed on a top surface of the moveable beam; and
a bottom electrode formed over the electrically insulating layer, wherein the bottom electrode contacts the piezoelectric region.

14. The sensor system of claim 13, wherein the bottom electrode and the top electrode are each electrically coupled to the light source, and wherein the moveable beam is not electrically coupled to the piezoelectric region.

15. The sensor system of claim 12, wherein the piezoelectric sensor and the light source are electrically coupled by one or more conductive traces.

16. The sensor system of claim 15, wherein the conductive traces are meandering traces.

17. The sensor system of claim 8, further comprising:
an electrical output conditioning circuit electrically coupled to the piezoelectric sensor, wherein the electrical output conditioning circuit modifies the electrical output signal generated by the piezoelectric sensor before it is delivered to the light source.

18. The sensor system of claim 17, wherein the electrical output conditioning circuit includes an amplifier and/or a comparator.

19. A method of forming a piezoelectric sensor, comprising:
forming a beam over an organic substrate;
depositing a piezoelectric material over portions of the beam, wherein the piezoelectric layer has a substantially amorphous crystal structure;
crystallizing the piezoelectric material with a pulsed laser anneal, wherein a temperature of the organic substrate does not exceed 260° C.;
forming an electrode over a top surface of the piezoelectric material; and
forming a cavity below a portion of the beam.

20. The method of claim 19, wherein the piezoelectric layer is deposited with a sputtering or ink-jetting process.

21. The method of claim 19, wherein the cavity is formed with a reactive ion etching process.

22. The method of claim 19, wherein the piezoelectric layer and the second electrode do not completely cover a top surface of the first electrode.

23. A sensor system for controlling a machine, comprising:
an organic substrate;
a piezoelectric sensor coupled to the organic substrate;
a light source electrically coupled to the piezoelectric sensor, wherein an intensity of light emitted by the light source is at least partially controlled by an electrical output signal generated by the piezoelectric sensor;
an electrical output conditioning circuit electrically coupled to the piezoelectric sensor, wherein the electrical output conditioning circuit modifies the electrical output signal generated by the piezoelectric sensor before it is delivered to the light source; and
a photodetector mounted remotely from the organic substrate.

24. The sensor system of claim 23, wherein the piezoelectric sensor comprises:
a cavity formed into the organic substrate;
a moveable beam formed over the cavity and anchored to the organic substrate;
a piezoelectric region formed over an end portion of the moveable beam, wherein the piezoelectric region extends at least partially over the cavity; and
a top electrode formed over a top surface of the piezoelectric region.

25. The sensor system of claim 24, wherein the piezoelectric sensor further comprises:
an electrically insulating layer formed on a top surface of the moveable beam; and
a bottom electrode formed over the electrically insulating layer, wherein the bottom electrode contacts the piezoelectric region.
